(19) United States
(12) Patent Application Publication
(10) Pub. No.: US 2026/0244810 A1
(43) Pub. Date: Aug. 20, 2026

(54) RELIABILITY ANALYTICS MODEL FOR HIGH ENERGY PUMPS

(71) Applicant: SAUDI ARABIAN OIL COMPANY, Dhahran (SA)

(72) Inventors: Najamulhasan S. TIRMEZI, Dhahran (SA); Surendra BHARTI, Dhahran (SA); Abdulaziz F. ALSAIF, Dhahran (SA); Badr M. ALRADDADI, Dhahran (SA)

(73) Assignee: SAUDI ARABIAN OIL COMPANY, Dhahran (SA)

(21) Appl. No.: 19/059,044

(22) Filed: Feb. 20, 2025

(51) Int. Cl. G06F 30/17

(52) U.S. Cl. CPC G06F 30/17

(57) ABSTRACT

A computer implemented method for assessing the condition of a high energy pump by applying a reliability analytics model (RAM) includes receiving, by a processor, in connection with the high energy pump, maintenance history information, performance review information, and condition report information; analyzing, by the processor, the received maintenance history information, performance review information, and condition report information, wherein analyzing the performance review information includes a comparison with OEM (original equipment manufacturer) performance parameters; grading, with the processor, the high energy pump based on said analyzing; and generating a report with the processor of the health of the high energy pump reflecting the grading.

### FIELD OF THE DISCLOSURE

The present disclosure relates generally to assessing the health of high energy pumps and, more particularly, to assessing the condition of a high energy pump by applying a reliability analytics model (RAM).

### BACKGROUND OF THE DISCLOSURE

High energy pumps are indispensable tools in the oil industry, and are used across various stages of the production process. Their ability to handle high pressures and volumes makes them crucial for efficient and reliable operations. In upstream applications, for example when pressure declines in mature oil fields, they can be used to provide artificial lift. Submersible pumps and progressive cavity pumps (PCPs) are used to lift oil to the surface. High-pressure mud pumps circulate drilling fluid to cool and lubricate the drill bit, remove cuttings, and maintain wellbore stability. In addition, pumps are used for well stimulation, injecting fluids at high pressures to fracture the formation and increase oil recovery. In midstream applications, high energy pumps are used for pipeline transport, moving crude oil and refined products through long-distance pipelines, overcoming pressure drops and maintaining flow rates. They are also used to transfer material, such as oil, between storage tanks and other facilities, and, in offshore platforms, they can be used to desalinate water for various operations. In addition, in downstream applications, high-energy pumps are pivotal in various processes involved in refining, processing, and distributing petroleum products.

In all these applications, high-energy pumps must be robust, reliable, and capable of handling the high pressures, temperatures, and corrosive environments typical of operations in the oil industry. Their efficiency and performance are critical to ensuring smooth and safe operations throughout the entire process.

### SUMMARY OF THE DISCLOSURE

Various details of the present disclosure are hereinafter summarized to provide a basic understanding. This summary is not an exhaustive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

According to certain embodiments consistent with the present disclosure, a computer implemented method for assessing the condition of a high energy pump by applying a reliability analytics model (RAM) includes receiving, by a processor, in connection with the high energy pump, maintenance history information, performance review information, and condition report information; analyzing, by the processor, the received maintenance history information, performance review information, and condition report information, wherein analyzing the performance review information includes a comparison with OEM (original equipment manufacturer) performance parameters; grading, with the processor, the high energy pump based on said analyzing; and generating a report with the processor of the health of the high energy pump reflecting the grading.

According to certain embodiments consistent with the present disclosure, a system includes memory to store computer executable instructions and one or more processors, operatively coupled to the memory, that execute the computer executable instructions to implement: a reliability analytics model (RAM) assessor operable to receive in connection with a high energy pump, maintenance history information, performance review information, and condition report information; an analyzer operable to analyze the received maintenance history information, performance review information, and condition report information, wherein analyzing the performance review information includes a comparison with OEM performance parameters; and a grader operable to grade the high energy pump based on said analyzing and to generate a report of the health of the high energy pump reflecting the grading.

According to certain embodiments consistent with the present disclosure, a machine-readable storage medium having stored thereon a computer program for assessing the condition of a high energy pump by applying a reliability analytics model (RAM) is disclosed. The computer program includes a routine of set instructions for causing the machine to perform the steps of: receiving, in connection with the high energy pump, maintenance history information, performance review information, and condition report information; analyzing the received maintenance history information, performance review information, and condition report information, wherein analyzing the performance review information includes a comparison with OEM performance parameters; grading the high energy pump based on said analyzing; and generating a report with the processor of the health of the high energy pump reflecting the grading.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is a block diagram of a system for assessing the condition of a high energy pump by applying a reliability analytics model in accordance with certain embodiments.

FIG. 2 is a flow diagram of an example method for assessing the condition of a high energy pump by applying a reliability analytics model (RAM) in accordance with certain embodiments.

FIG. 3 is a block diagram of a computer system that may be used to implement one or more of the systems or methods described herein in accordance with certain embodiments.

FIG. 4 depicts a cloud computing environment that can be used to perform one or more actions according to an aspect of the present disclosure.

### DETAILED DESCRIPTION

Embodiments of the present disclosure will now be described in detail with reference to the accompanying drawing figures. Like elements in the various figures may be denoted by like reference numerals. Further, in the following detailed description, specific details are set forth in order to provide a more thorough understanding of the claimed subject matter. However, it will be apparent to one of ordinary skill in the art that the embodiments disclosed herein may be practiced without these specific details, or with details that are not described herein in the interest of clarity. Thus in some instances, well-known features have not been described in detail to avoid unnecessarily complicating the description. Additionally, it will be apparent to one of ordinary skill in the art that the scale of the elements presented in the accompanying drawing figures may vary without departing from the scope of the present disclosure.

Embodiments in accordance with the present disclosure generally relate to systems and methods for assessing the condition a high energy pump by applying a reliability analytics model (RAM).

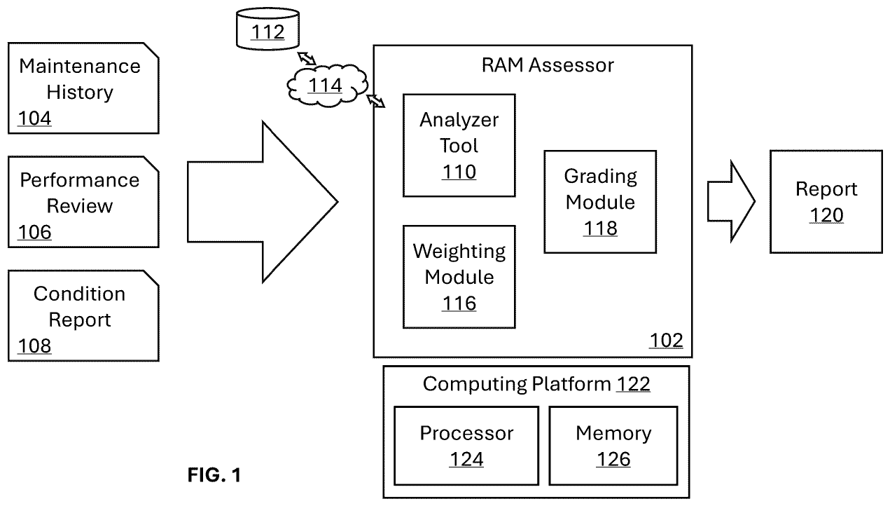

FIG. 1 is a block diagram of a system 100 for assessing the condition of a high energy pump by applying a reliability analytics model in accordance with certain embodiments. System 100 comprises a RAM assessor 102 that receives as input three general types of information relating to a particular high energy pump of interest. The first of these is maintenance history 104, and includes information about any overhauls conducted or work orders associated with the high energy pump, and for example the number of years since the last overhaul of the pump. The second type of information received by RAM assessor 102 in connection with the high energy pump of interest is performance review information 106. This information includes operating parameters of the high energy pump, such as speed, efficiency, vibration, valve condition, power draw, flow, pressure, output, temperature and the like, and any curves and graphs reflecting these and other parameters and relationships. The third type of information received by RAM assessor 102 relates to pump condition 108. This information can include a periodic vibration survey, bad actor report about the pump of interest, open corporate technical alerts (CTAs) relating to the pump, and the like. In certain embodiments, any pump of a facility that is flagged for high vibration in a monthly vibration survey or appears in a bad actor report or has an open CTA is selected and information thereof provided to RAM assessor 102 as pump condition information 108.

RAM assessor 102 includes analyzer tool 110 operative to receive and analyze the three general types of information relating to a particular high energy pump of interest. Using the received maintenance history 104, analyzer tool 110 can assess work orders in Computerized Maintenance Management System (CMMS) to establish probable failure modes and heuristic probability of failure. In certain embodiments, pumps without a complete overhaul in the past ten years (or similar selectable timeframe) can be assigned a high probability of failure by the analyzer tool. Analyzer tool 110 also uses the performance review information 106 to conduct a comparison with OEM (original equipment manufacturer) original factory acceptance test curves and typical curves, as well as any OEM performance parameters, using for example a numerical analysis model developed in SEEQ™. (SEEQ™ is an advanced analytics software solution developed by SEEQ Corporation which utilizes advanced analytics, machine learning and artificial intelligence for time series data in an interactive and intuitive method for engineers in process manufacturing organizations to accelerate investigation and decision making.) The original factory acceptance test curves and typical curves and any OEM performance parameters can be stored locally or remotely in a database 112 and accessed over a network 114 in certain embodiments. Analyzer 110 can identify deviations in actual pump performance versus the original pump design parameters. A high deviation can be used to indicate a high probability of failure. Analyzer 110 also uses the pump condition information 108 to flag pumps deemed problematic from bad actor reports and open corporate technical alerts (CTAs).

RAM assessor 102 includes a weighting module 116 operative to assign weights to the three general types of information received and analyzed by analyzer tool 110. The weights may be user selectable. In one example, the analyzed maintenance history information 104 may be assigned a weight of 40%; the analyzed performance review information 106 may be assigned a weight of 30%; and the analyzed pump condition information 108 may be assigned a weight of 30%. Different percentage assignments are also contemplated.

RAM assessor 102 also includes a grading module 118 operative to generate an overall report 120 of the health of the high energy pump under examination based on the weighted information from weighting module 116. TABLE 1 below is an example of grading assignments implemented by grading module 118 in accordance with certain embodiments. The grading assignments inure to various year ranges since last overhaul in the Overhaul History section; to various condition levels in the Performance Review section; and to various alert numbers or levels in the Condition Report Review section. TABLE 2 reflects a tally of the grades to achieve an overall score and corresponding health outcome that may be ascribed to the high energy pump of interest and that may further be reflected in the report 120 in FIG. 1.

TABLE 1

| | Pump Health Scoring System | | |
|---|---|---|---|
| Categories | Grade | Condition | Weightage |
| Overhaul History Review | 3-4 | (0~3) Years | 40% |
| (No. of Years Since last | 2-3 | (3~6) Years | |
| Overhaul) | 1 | (7~10+) Years | |
| Performance Review | 3 | Acceptable (0-5%) | 30% |
| (Pump Head Deviation) | 2 | Marginal (6-9%) | |
| | 1 | Bad (10%) | |
| Condition Report Review | 3 | No Alerts | 30% |
| (Corporate Technical Alter, | 2 | 1 Alert | |
| Operations Bad Actor Report, | 1 | 2+ Alerts | |
| Reliability Vibration Report) | | | |

| | | |
|---|---|---|
| Total | 10 | 100% |

TABLE 2

| Score | Outcome |
|---|---|
| ≥7 | Healthy |
| 5~6 | Watchlist |
| ≤4 | Unhealthy |

In accordance with certain embodiments, if the pump aggregated score determined by grading module 118 based on TABLE 2 is Healthy, with an aggregated score of 7 or more, this indicates that the pump can remain in service as usual. Similarly, with an aggregated score of 4 or less than 4 (unhealthy), the pump is recommended for an overhaul. A score between these two ranges may be considered on a watchlist. Thus this approach provides a guidance to the management of an operating facility for devising an operational and maintenance strategy. An aggregated score against each of the three factors, reveals a comprehensive picture of pump health condition. The developed methodology comprehensively evaluates and encapsulates all the necessary vital factors in decision making utilizing an objective and quantitative way to reveal the comprehensive health condition.

The above-described approach may be dependent on the instrumentation employed, vibration data collection, valve health condition, and pump field checks for any abnormality, hence it may be particularly important in some embodiments to ensure the accuracy of these parameters. In addition, as a pre-requisite, calibration of the transmitter employed for measuring pump flow and pressure parameters need to be ensured before collecting data in some embodiments.

The system 100 can be implemented using one or more modules, shown in block form in the drawings. The one or more modules can be in software or hardware form, or a combination thereof. In some examples, the system 100 or portions thereof can be implemented as machine readable instructions for execution on one or more computing platforms 122 (referred to as a computing platform herein), as shown in FIG. 1. The computing platform 122 can include one or more computing devices selected from, for example, a desktop computer, a server, a controller, a blade, a mobile phone, a tablet, a laptop, a personal digital assistant (PDA), and the like.

In certain embodiments, the RAM assessor 102 can be implemented as using a computing platform 122 and can include a processor 124 and a memory 126. By way of example, the memory 126 can be implemented, for example, as a non-transitory computer storage medium, such as volatile memory (e.g., random access memory), non-volatile memory (e.g., a hard disk drive, a solid-state drive, a flash memory, or the like), or a combination thereof. The processor 124 can be implemented, for example, as one or more processor cores. The memory 126 can store machine-readable instructions that can be retrieved and executed by the processor 124 to implement one or modules of the RAM assessor 102. Each of the processor 124 and the memory 126 can be implemented on a similar or a different computing platform. The computing platform 122 can be implemented in a cloud computing environment (for example, as disclosed herein) and thus on a cloud infrastructure. In such a situation, features of the computing platform 122 can be representative of a single instance of hardware or multiple instances of hardware executing across the multiple of instances (e.g., distributed) of hardware (e.g., computers, routers, memory, processors, or a combination thereof). Alternatively, the computing platform 122 can be implemented on a single dedicated server or workstation.

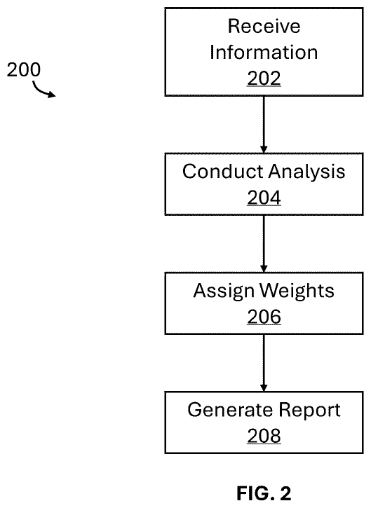

In view of the structural and functional features described above, example methods will be better appreciated with reference to FIG. 2. While, for purposes of simplicity of explanation, the example methods of FIG. 2 are shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the methods, and conversely, some actions may be performed that are omitted from the description.

FIG. 2 is an example of a method 200 for assessing the condition of a high energy pump by applying a reliability analytics model (RAM) in accordance with certain embodiments. The method 200 can be implemented by RAM assessor 102 as shown in FIG. 1. Method 200 begins at 202 with the receipt, for example by RAM assessor 102, of three general types of information relating to a particular high energy pump of interest. These for example can be maintenance history 104, performance review information 106 and/or condition reports 108 as explained above. At 204, the received information is analyzed for example by analyzer tool 110 in the manner described above. For instance, work orders can be assessed to establish probable failure modes and heuristic probability of failure, depending on overhaul history, comparison with OEM parameters, etc. At 206, weights are assigned to the analyzed information, for example by a weighting module 116, and at 208, a health report is generated, for example by grading module 118, reflecting the overall health of the pump of interest.

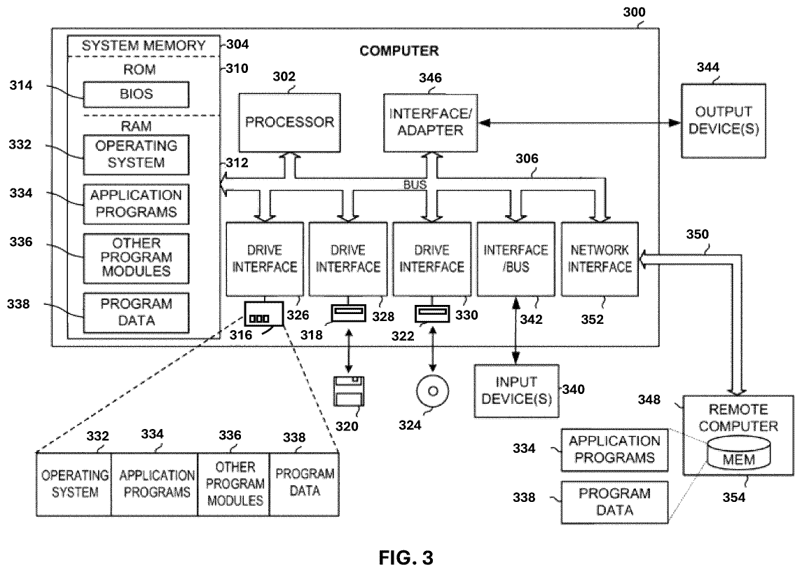

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 3. Furthermore, portions of the embodiments may be a computer program product on a computer-readable storage medium having computer readable program code on the medium. Any non-transitory, tangible storage media possessing structure may be utilized including, but not limited to, static and dynamic storage devices, volatile and non-volatile memories, hard disks, optical storage devices, and magnetic storage devices, but excludes any medium that is not eligible for patent protection under 35 U.S.C. § 101 (such as a propagating electrical or electromagnetic signals per se). As an example and not by way of limitation, computer-readable storage media may include a semiconductor-based circuit or device or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. A computer-readable non-transitory storage medium may be volatile, nonvolatile, or a combination of volatile and non-volatile, as appropriate.

Certain embodiments have also been described herein with reference to block illustrations of methods, systems, and computer program products. It will be understood that blocks and/or combinations of blocks in the illustrations, as well as methods or steps or acts of processes described herein, can be implemented by a computer program comprising a routine of set instructions stored in a machine-readable storage medium as described herein. These instructions may be provided to one or more processors of a general purpose computer, special purpose computer, or other programmable data processing apparatus (or a combination of devices and circuits) to produce a machine, such that the instructions of the machine, when executed by the processor, implement the functions specified in the block or blocks, or in the acts, steps, methods and processes described herein.

These processor-executable instructions may also be stored in computer-readable memory that can direct a computer or other programmable data processing apparatus to function in a particular manner, such that the instructions stored in the computer-readable memory result in an article of manufacture including instructions which implement the function specified. The computer program instructions may also be loaded onto a computer or other programmable data processing apparatus to cause a series of operational steps to be performed on the computer or other programmable apparatus to realize a computer implemented process such that the instructions which execute on the computer or other programmable apparatus provide steps for implementing the functions specified in flowchart blocks that may be described herein.

In this regard, FIG. 3 illustrates one example of a computer system 300 that can be employed to execute one or more embodiments of the present disclosure. Computer system 300 can be implemented on one or more general purpose networked computer systems, embedded computer systems, routers, switches, server devices, client devices, various intermediate devices/nodes or standalone computer systems. Additionally, computer system 300 can be implemented on various mobile clients such as, for example, a personal digital assistant (PDA), laptop computer, pager, and the like, provided it includes sufficient processing capabilities.

Computer system 300 includes processing unit 302, system memory 304, and system bus 306 that couples various system components, including the system memory 304, to processing unit 302. System memory 304 can include volatile (e.g. RAM, DRAM, SDRAM, Double Data Rate (DDR) RAM, etc.) and non-volatile (e.g. Flash, NAND, etc.) memory. Dual microprocessors and other multi-processor architectures also can be used as processing unit 302. System bus 306 may be any of several types of bus structure including a memory bus or memory controller, a peripheral bus, and a local bus using any of a variety of bus architectures. System memory 304 includes read only memory (ROM) 310 and random access memory (RAM) 312. A basic input/output system (BIOS) 314 can reside in ROM 310 containing the basic routines that help to transfer information among elements within computer system 300.

Computer system 300 can include a hard disk drive 316, magnetic disk drive 318, e.g., to read from or write to removable disk 320, and an optical disk drive 322, e.g., for reading CD-ROM disk 324 or to read from or write to other optical media. Hard disk drive 316, magnetic disk drive 318, and optical disk drive 322 are connected to system bus 306 by a hard disk drive interface 326, a magnetic disk drive interface 328, and an optical drive interface 330, respectively. The drives and associated computer-readable media provide nonvolatile storage of data, data structures, and computer-executable instructions for computer system 300. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and described herein.

A number of program modules may be stored in drives and RAM 310, including operating system 332, one or more application programs 334, other program modules 336, and program data 338. In some examples, the application programs 334 can include RAM assessor 102 and/or analyzer tool 110, weighting module 116 and grading module 118, for instance, and the program data 338 can include maintenance history 104, performance review information 106, and condition report information 108, as well original factory acceptance test curves and typical curves and any OEM performance parameters. The application programs 334 and program data 338 can include functions and methods programmed to perform any of the function described herein.

A user may enter commands and information into computer system 300 through one or more input devices 340, such as a pointing device (e.g., a mouse, touch screen), keyboard, microphone, joystick, game pad, scanner, and the like. For instance, the user can employ input device 340 to edit or modify or enter weights into weighting module 116 as described above. These and other input devices 340 are often connected to processing unit 302 through a corresponding port interface 342 that is coupled to the system bus, but may be connected by other interfaces, such as a parallel port, serial port, or universal serial bus (USB). One or more output devices 344 (e.g., display, a monitor, printer, projector, or other type of displaying device) is also connected to system bus 306 via interface 346, such as a video adapter.

Computer system 300 may operate in a networked environment using logical connections to one or more remote computers, such as remote computer 348. Remote computer 348 may be a workstation, computer system, router, peer device, or other common network node, and typically includes many or all the elements described relative to computer system 300. The logical connections, schematically indicated at 350, can include a local area network (LAN) and/or a wide area network (WAN), or a combination of these, and can be in a cloud-type architecture, for example configured as private clouds, public clouds, hybrid clouds, and multi-clouds. When used in a LAN networking environment, computer system 300 can be connected to the local network through a network interface or adapter 352. When used in a WAN networking environment, computer system 300 can include a modem, or can be connected to a communications server on the LAN. The modem, which may be internal or external, can be connected to system bus 306 via an appropriate port interface. In a networked environment, application programs 334 or program data 338 depicted relative to computer system 300, or portions thereof, may be stored in a remote memory storage device 354.

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models (e.g., software as a service (Saas, platform as a service (PaaS), and/or infrastructure as a service (IaaS)) and at least four deployment models (e.g., private cloud, community cloud, public cloud, and/or hybrid cloud). A cloud computing environment can be service oriented with a focus on statelessness, low coupling, modularity, and semantic interoperability.

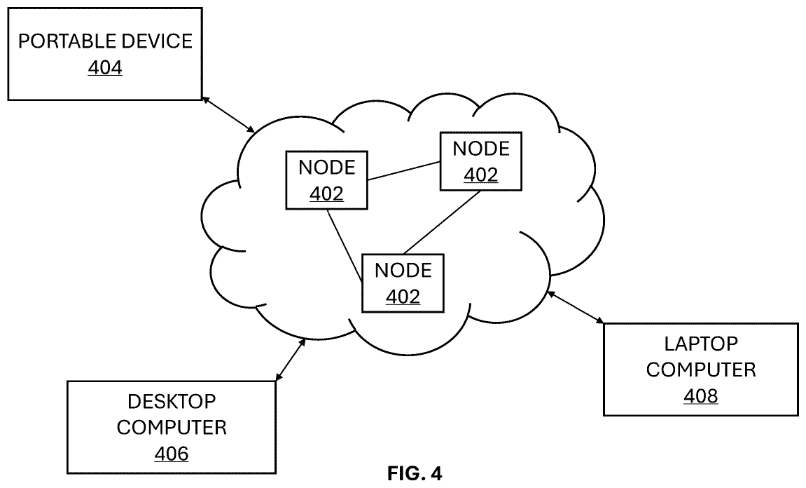

FIG. 4 is an example of a cloud computing environment 400 that can be used for implementing one or more modules and/or systems in accordance with one or more examples, as disclosed herein, Thus, reference can be made to one or more examples of FIGS. 1-3 in the example of FIG. 4. As shown, cloud computing environment 400 can include one or more cloud computing nodes 402 with which local computing devices used by cloud consumers (or users), such as, for example, personal digital assistant (PDA), cellular, or portable device 404, a desktop computer 406, and/or a laptop computer 408, may communicate. The computing nodes 402 can communicate with one another. In some examples, the computing nodes 402 can be grouped (not shown) physically or virtually, in one or more networks, such as Private, Community, Public, or Hybrid clouds, or a combination thereof. This allows the cloud computing environment 400 to offer infrastructure, platforms and/or software as services for which a cloud consumer does not need to maintain resources on a local computing device. The devices 404-408, as shown in FIG. 4, are intended to be illustrative and that computing nodes 402 and cloud computing environment 400 can communicate with any type of computerized device over any type of network and/or network addressable connection (e.g., using a web browser). In some examples, the one or more computing nodes 402 are used for implementing one or more examples disclosed herein relating to root-source identification. Thus, in some examples, the one or more computing nodes can be used to implement modules, platforms, and/or systems, as disclosed herein.

In some examples, the cloud computing environment 400 can provide one or more functional abstraction layers. It is to be understood that the cloud computing environment 400 need not provide all of the one or more functional abstraction layers (and corresponding functions and/or components), as disclosed herein. For example, the cloud computing environment 400 can provide a hardware and software layer that can include hardware and software components. Examples of hardware components include: mainframes; RISC (Reduced Instruction Set Computer) architecture based servers; servers; blade servers; storage devices; and networks and networking components. In some embodiments, software components include network application server software and database software.

In some examples, the cloud computing environment 400 can provide a virtualization layer that provides an abstraction layer from which the following examples of virtual entities may be provided: virtual servers; virtual storage; virtual networks, including virtual private networks; virtual applications and operating systems; and virtual clients. In some examples, the cloud computing environment 400 can provide a management layer that can provide the functions described below. For example, the management layer can provide resource provisioning that can provide dynamic procurement of computing resources and other resources that are utilized to perform tasks within the cloud computing environment. The management layer can also provide metering and pricing to provide cost tracking as resources are utilized within the cloud computing environment 400, and billing or invoicing for consumption of these resources. In one example, these resources may include application software licenses. Security provides identity verification for cloud consumers and tasks, as well as protection for data and other resources. The management layer can also provide a user portal that provides access to the cloud computing environment 400 for consumers and system administrators. The management layer can also provide service level management, which can provide cloud computing resource allocation and management such that required service levels are met. Service Level Agreement (SLA) planning and fulfillment can also be provided to provide pre-arrangement for, and procurement of, cloud computing resources for which a future requirement is anticipated in accordance with an SLA.

In some examples, the cloud computing environment 400 can provide a workloads layer that provides examples of functionality for which the cloud computing environment 400 may be utilized. Examples of workloads and functions which may be provided from this layer include: mapping and navigation; software development and lifecycle management; virtual classroom education delivery; data analytics processing; and transaction processing, Various embodiments of the present disclosure can utilize the cloud computing environment 400.

The present disclosure is also directed to the following exemplary embodiments, which can be practiced in any combination thereof:

A. A computer implemented method for assessing the condition of a high energy pump by applying a reliability analytics model (RAM) includes receiving, by a processor, in connection with the high energy pump, maintenance history information, performance review information, and condition report information; analyzing, by the processor, the received maintenance history information, performance review information, and condition report information, wherein analyzing the performance review information includes a comparison with OEM (original equipment manufacturer) performance parameters; grading, with the processor, the high energy pump based on said analyzing; and generating a report with the processor of the health of the high energy pump reflecting said grading.

B. A system includes memory to store computer executable instructions and one or more processors, operatively coupled to the memory, that execute the computer executable instructions to implement: a reliability analytics model (RAM) assessor operable to receive in connection with a high energy pump, maintenance history information, performance review information, and condition report information; an analyzer operable to analyze the received maintenance history information, performance review information, and condition report information, wherein analyzing the performance review information includes a comparison with OEM (original equipment manufacturer) performance parameters; and a grader operable to grade the high energy pump based on said analyzing and to generate a report of the health of the high energy pump reflecting said grading.

C. A machine-readable storage medium having stored thereon a computer program for assessing the condition of a high energy pump by applying a reliability analytics model (RAM) is disclosed. The computer program includes a routine of set instructions for causing the machine to perform the steps of: receiving, in connection with the high energy pump, maintenance history information, performance review information, and condition report information; analyzing the received maintenance history information, performance review information, and condition report information, wherein analyzing the performance review information includes a comparison with OEM (original equipment manufacturer) performance parameters; grading the high energy pump based on said analyzing; and generating a report with the processor of the health of the high energy pump reflecting said grading.

Each of embodiments A through C may have one or more of the following additional elements in any combination: Element 1: analyzing the received maintenance history information comprises determining time of last overhaul. Element 2: weighting the results of said analyzing. Element 3: weighting is user-selectable. Element 4: weighting comprises 40% weight to maintenance history information, 30% weight to the performance review information, and 30% weight to the condition report information.

The present invention may be a system, a method, and/or a computer program product at any possible technical detail level of integration. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or carry out combinations of special purpose hardware and computer instructions.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation used herein are merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, if used herein, the terms “coupled” or “coupled to” or “connected” or “connected to” or “attached” or “attached to” may indicate establishing either a direct or indirect connection, and is not limited to either unless expressly referenced as such. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The term “based on” means “based at least in part on.” The terms “about” and “approximately” can be used to include any numerical value that can vary without changing the basic function of that value. When used with a range, “about” and “approximately” also disclose the range defined by the absolute values of the two endpoints, e.g. “about 2 to about 4” also discloses the range “from 2 to 4.” Generally, the terms “about” and “approximately” may refer to plus or minus 5-10% of the indicated number.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

The invention claimed is:

1. A computer implemented method for assessing the condition of a high energy pump by applying a reliability analytics model (RAM), the method comprising:
receiving, by a processor, in connection with the high energy pump, maintenance history information, performance review information, and condition report information;
analyzing, by the processor, the received maintenance history information, performance review information, and condition report information, wherein analyzing the performance review information includes a comparison with OEM (original equipment manufacturer) performance parameters;
grading, with the processor, the high energy pump based on said analyzing; and
generating a report with the processor of the health of the high energy pump reflecting said grading.

2. The method of claim 1, wherein analyzing the received maintenance history information comprises determining time of last overhaul.

3. The method of claim 1, further comprising weighting the results of said analyzing.

4. The method of claim 3, wherein said weighting is user-selectable.

5. The method of claim 5, wherein said weighting comprises 40% weight to maintenance history information, 30% weight to the performance review information, and 30% weight to the condition report information.

6. A system, comprising:
memory to store computer executable instructions; and
one or more processors, operatively coupled to the memory, that execute the computer executable instructions to implement:
a reliability analytics model (RAM) assessor operable to receive in connection with a high energy pump, maintenance history information, performance review information, and condition report information;
an analyzer operable to analyze the received maintenance history information, performance review information, and condition report information, wherein analyzing the performance review information includes a comparison with OEM (original equipment manufacturer) performance parameters; and
a grader operable to grade the high energy pump based on said analyzing and to generate a report of the health of the high energy pump reflecting said grading.

7. The system of claim 6, wherein analyzing the received maintenance history information comprises determining time of last overhaul.

8. The system of claim 6, wherein the instructions further implement weighting the results of said analyzing.

9. The system of claim 8, wherein said weighting is user-selectable.

10. The system of claim 8, wherein said weighting comprises 40% weight to maintenance history information, 30% weight to the performance review information, and 30% weight to the condition report information.

11. A machine-readable storage medium having stored thereon a computer program for assessing the condition of a high energy pump by applying a reliability analytics model (RAM), the computer program comprising a routine of set instructions for causing the machine to perform the steps of:
receiving, in connection with the high energy pump, maintenance history information, performance review information, and condition report information;
analyzing the received maintenance history information, performance review information, and condition report information, wherein analyzing the performance review information includes a comparison with OEM (original equipment manufacturer) performance parameters;
grading the high energy pump based on said analyzing; and
generating a report with the processor of the health of the high energy pump reflecting said grading.

12. The machine-readable storage medium of claim of claim 11, wherein analyzing the received maintenance history information comprises determining time of last overhaul.

13. The machine-readable storage medium of claim 11, the set of instructions further causing the machine to perform the steps of:
weighting the results of said analyzing.

14. The machine-readable storage medium of claim 13, wherein said weighting is user-selectable.

15. The machine-readable storage medium of claim 13, wherein said weighting comprises 40% weight to maintenance history information, 30% weight to the performance review information, and 30% weight to the condition report information.
